(19) United States
(12) Patent Application Publication
(10) Pub. No.: US 2005/0241467 A1
(43) Pub. Date: Nov. 3, 2005

(54) Modular electronic musical keyboard instrument

(76) Inventor: Amanda Lo, Taipei City (TW)

Correspondence Address: MARSHALL & MELHORN, FOUR SEAGATE, EIGHT FLOOR, TOLEDO, OH, 43604, US

(21) Appl. No.: 10/823,959

(22) Filed: Apr. 14, 2004

(51) Int. Cl. H03C 1/00; G10H 1/04; G10H 7/00; G10H 1/32; G10H 3/00

(52) U.S. Cl. 84/744

(57) ABSTRACT

A modular electronic musical keyboard instrument includes a plurality of keyboard modules, a signal bus, a plurality of connecting devices, and a signal port. Each of the keyboard modules includes a module casing, a set of signal switches, and a set of finger keys associated operably and respectively with the signal switches. The signal bus includes a plurality of signal lines, each of which is connected electrically to a corresponding one of the signal switches. The signal bus is divided into a plurality of bus sections, each of which is disposed in the module casing of a respective one of the keyboard modules. Each of the connecting devices connects electrically the bus sections of a corresponding adjacent pair of the keyboard modules when the keyboard modules are disposed side by side to form an elongate keyboard body. The signal port is connected electrically to the signal bus.

### BACKGROUND OF THE INVENTION

1. Field of the Invention

The present invention relates to an electronic musical keyboard instrument, more particularly to a modular electronic musical keyboard instrument.

2. Description of the Related Art

Conventional electronic musical keyboard instruments are disadvantageous in that the sizes thereof, which are proportional to the number of their finger keys, are relatively large. In some instances, the lengths of the conventional electronic musical keyboard instruments can reach up to a meter such that they are inconvenient to carry and store.

### SUMMARY OF THE INVENTION

Therefore, the object of the present invention is to provide a modular electronic musical keyboard instrument so as to overcome the aforesaid drawbacks of the prior art.

Accordingly, the modular electronic musical keyboard instrument of the present invention comprises a plurality of keyboard modules, a signal bus, a plurality of connecting devices, and a signal port. Each of the keyboard modules includes a module casing, a set of signal switches mounted on the module casing, and a set of finger keys mounted operably on the module casing and associated operably and respectively with the signal switches for controlling activation and deactivation of the signal switches. The signal bus includes a plurality of signal lines, each of which is connected electrically to a corresponding one of the signal switches. The signal bus is divided into a plurality of bus sections, each of which is disposed in the module casing of a respective one of the keyboard modules. Each of the connecting devices connects electrically the bus sections of a corresponding adjacent pair of the keyboard modules when the module casings of the keyboard modules are disposed side by side to form an elongate keyboard body. The signal port is connected electrically to the signal bus.

### BRIEF DESCRIPTION OF THE DRAWINGS

Other features and advantages of the present invention will become apparent in the following detailed description of the preferred embodiments with reference to the accompanying drawings, of which:

FIG. 1 is a schematic top view of the first preferred embodiment of a modular electronic musical keyboard instrument according to the present invention;

FIG. 2 is a schematic circuit diagram to illustrate electrical components of the first preferred embodiment;

FIG. 3 is a fragmentary, partly exploded, perspective view of the first preferred embodiment, illustrating a connecting device between an adjacent pair of keyboard modules;

FIG. 4 is a schematic side view of the first preferred embodiment, illustrating how the keyboard modules are stacked to facilitate storage and transport;

FIG. 5 is a schematic front view of the first preferred embodiment, illustrating the keyboard modules when arranged in a stack;

FIG. 6 is a schematic front view of the first preferred embodiment, illustrating the keyboard modules when disposed side by side to form an elongate keyboard body;

FIG. 7 is a schematic top view of the second preferred embodiment of a modular electronic musical keyboard instrument according to the present invention;

FIG. 8 is a schematic circuit diagram to illustrate electrical components of the second preferred embodiment; and

FIG. 9 is a fragmentary, partly exploded, perspective view of the second preferred embodiment, illustrating a connecting device between an adjacent pair of keyboard modules.

### DETAILED DESCRIPTION OF THE PREFERRED EMBODIMENTS

Before the present invention is described in greater detail with reference to the accompanying preferred embodiments, it should be noted herein that like elements are denoted by the same reference numerals throughout the disclosure.

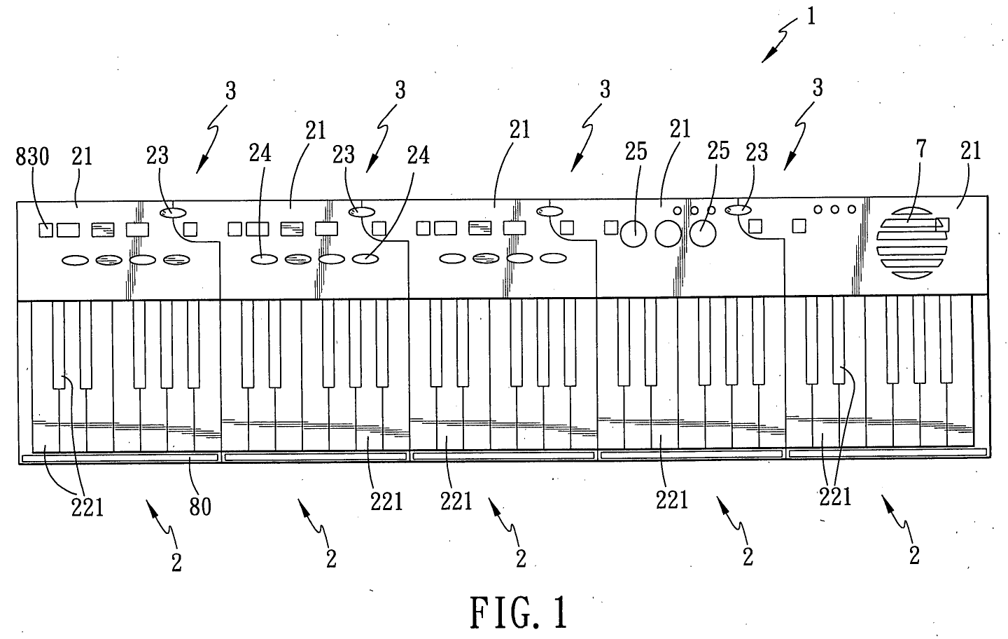

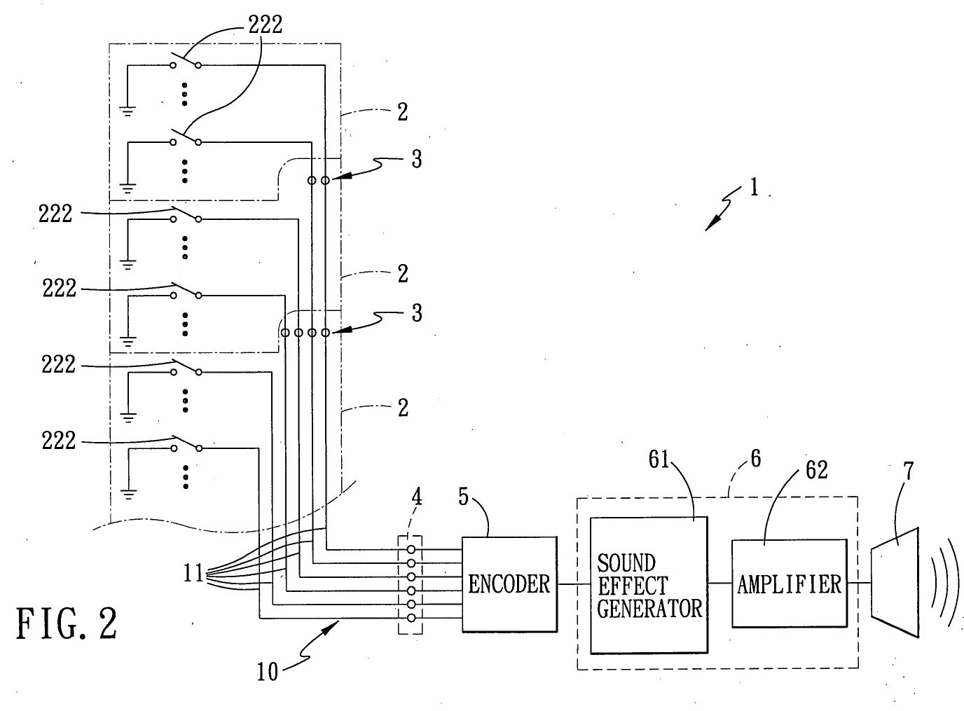

Referring to FIGS. 1 to 3, the first preferred embodiment of a modular electronic musical keyboard instrument 1 according to the present invention is shown to include a plurality of keyboard modules 2, a signal bus 10, a plurality of connecting devices 3, and a signal port 4 connected electrically to the signal bus 10. In this embodiment, the number of the keyboard modules 2 is five, and the number of the connecting devices 3 is four.

Each of the keyboard modules 2 includes a module casing 21, a set of signal switches 222 mounted on the module casing 21, and a set of finger keys 221 mounted operably on the module casing 21 and associated operably and respectively with the signal switches 222 for controlling activation and deactivation of the signal switches 222 in a known manner. In this embodiment, the finger keys 221 of each of the keyboard modules 2 include seven monotone keys 223 and five halftone keys 224, each of which is disposed between an adjacent pair of the monotone keys 223.

The signal bus 10 includes a plurality of signal lines 11, each of which is connected electrically to a corresponding one of the signal switches 222. The signal bus 10 is divided into a plurality of bus sections (in this embodiment, the number of the bus sections is five), each of which is disposed in the module casing 21 of a respective one of the keyboard modules 2.

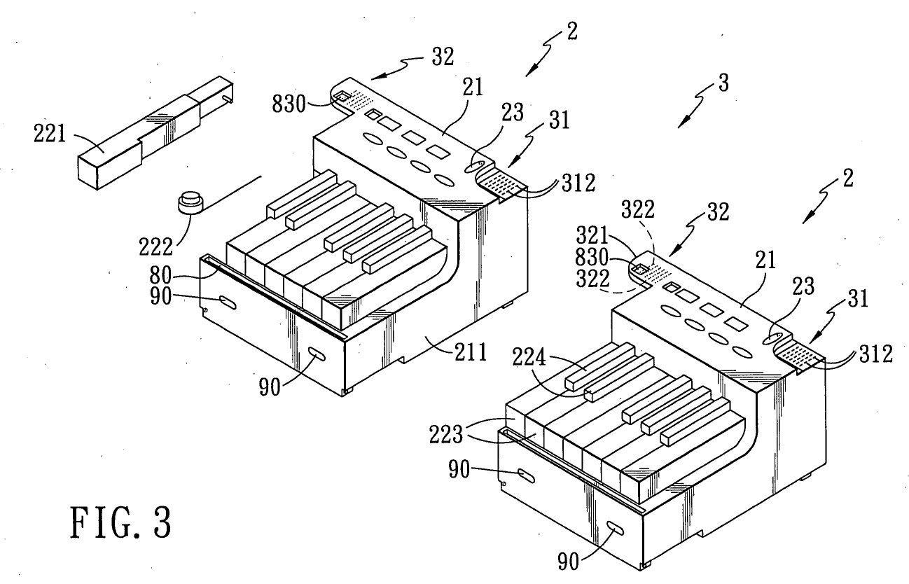

Each of the connecting devices 3 connects electrically the bus sections of a corresponding adjacent pair of the keyboard modules 2 when the module casings 21 of the keyboard modules 2 are disposed side by side to form an elongate keyboard body (see FIG. 1). As shown in FIG. 3, the module casings 21 of each adjacent pair of the keyboard modules 2 of the elongate keyboard body have confronting lateral walls 211. The module casing 21 of a first one of the keyboard modules 2 in each adjacent pair further has a top wall formed with a contact receiving recess 31 that opens to the lateral wall 211 thereof. The module casing 21 of a second one of the keyboard modules 2 in each adjacent pair is formed with a contact support plate 32 that extends removably into the contact receiving recess 31 of the module casing 21 of the first one of the keyboard modules 2. Each of the connecting devices 3 includes a set of first electrical contacts 312 mounted in the contact receiving recess 31 and connected electrically and respectively to the signal lines 11 of the bus section in the first one of the keyboard modules 2 of the corresponding adjacent pair. In this embodiment, the first electrical contacts 312 are arranged in an array and are in the form of resilient metal pieces that are designed to bend upon exertion of an external force. Each of the connecting devices 3 further includes a set of second electrical contacts 322 mounted on the contact support plate 32, connected electrically and respectively to the signal lines 11 of the bus section in the second one of the keyboard modules 2 of the corresponding adjacent pair, and connecting electrically and respectively with the first electrical contacts 312 when the contact support plate 32 is extended into the contact receiving recess 31. In this embodiment, the second electrical contacts 322 are arranged in an array and are in the form of metal pads.

Preferably, each of the connecting devices 3 further includes a press member 23 mounted movably on the top wall of the module casing 21 of the first one of the keyboard modules 2 in the corresponding adjacent pair of the keyboard modules 2 adjacent to the contact receiving recess 31. In this embodiment, the press member 23 is pivotable to a selected one of a pressing position, where the press member 23 presses the contact support plate 32 downward to ensure electrical connection between the first and second electrical contacts 312, 322, as best shown in FIG. 1, and a releasing position, where the press member 23 permits detachment of the contact support plate 32 from the contact receiving recess 31, as best shown in FIG. 3.

The modular electronic musical keyboard instrument 1 of this embodiment further comprises an encoder 5 coupled electrically to the signal port 4 and responsive to activation of the signal switches 222 that are connected to the encoder 5 via the signal bus 10 and the signal port 4 so as to generate a corresponding command, and a processor 6 coupled electrically to the encoder 5 and responsive to the command issued by the encoder 5 so as to generate a corresponding audio signal output. In this embodiment, the processor 6 includes a sound effect generator 61 coupled electrically to the encoder 5, and an amplifier 62 coupled electrically to the sound effect generator 61. The modular electronic musical keyboard instrument 1 of this embodiment further comprises a speaker 7 coupled to the amplifier 62 for reproducing the audio signal output of the processor 6. In this embodiment, the signal port 4, the encoder 5, the processor 6, and the speaker 7 are disposed in the module casing 21 of one of the keyboard modules 2. Moreover, the encoder 5 and the sound effect generator 61 are implemented using integrated circuits. In practice, the signal port 4, the encoder 5, the processor 6, and the speaker 7 may be disposed in different ones of the keyboard modules 2.

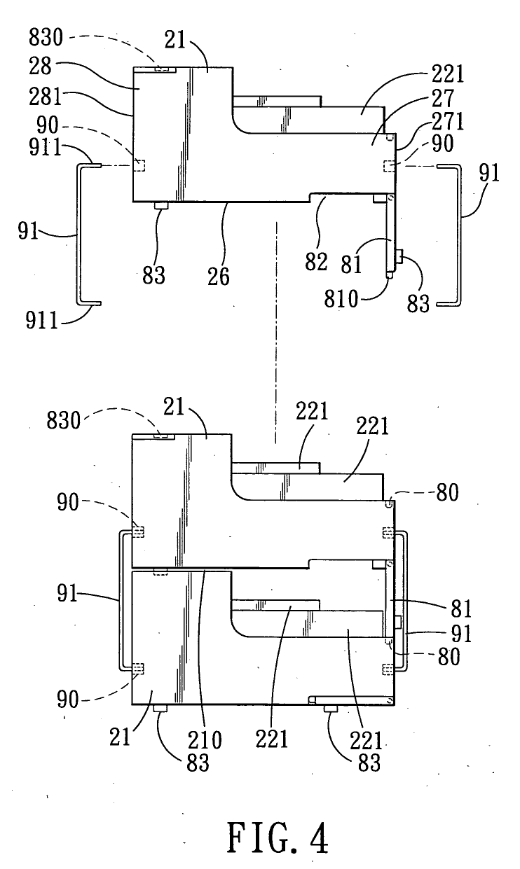

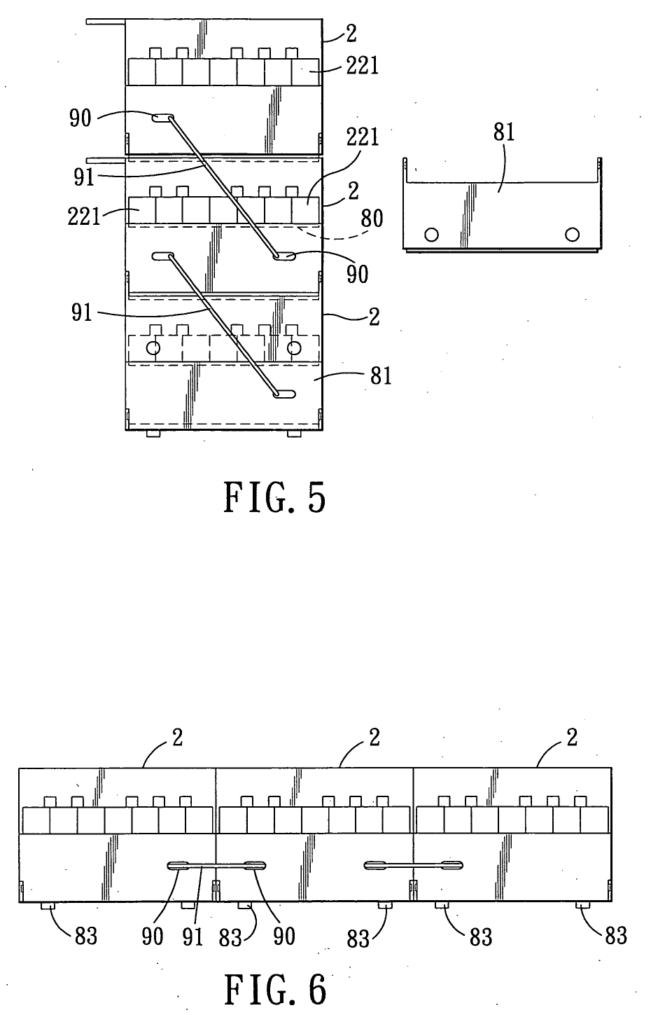

Referring to FIGS. 4 and 5, the keyboard modules 2 may be arranged in a stack to facilitate storage and handling of the modular electronic musical keyboard instrument 1 of this invention. As shown, the module casing 21 of each of the keyboard modules 2 has a front portion 27, a rear portion 28 that is raised relative to the front portion 27, and a bottom wall 26. The finger keys 221 are disposed on the front portion 27 of the module casing 21. The module casings 21 of the keyboard modules 2 are capable of being stacked one on top of the other such that the bottom wall 26 of the module casing 21 of an upper one of the keyboard modules 2 is supported on top of the rear portion 28 of the module casing 21 of a lower one of the keyboard modules 2, thereby forming the stack. The modular electronic musical keyboard instrument 1 further comprises a set of tie rods 91, each of which has opposite ends 911 connected removably to a corresponding pair of the keyboard modules 2 in the stack.

In this embodiment, the module casing 21 of each keyboard module 2 has front and rear walls 271, 281, at least one of which is formed with a rod engaging hole 90 such that the opposite ends 911 of each of the tie rods 91 extend removably into the rod engaging holes 90 in the corresponding pair of the keyboard modules 2 in the stack. In this embodiment, both the front and rear walls 271, 281 are formed with the rod engaging holes 90. Preferably, the tie rods 91 are stretchable to enhance the securing effect.

The module casing 21 of each keyboard module 2 further has a support member 81 connected foldably to the bottom wall 26 thereof and foldable away from the bottom wall 26 from a folded position to an unfolded position where the support member 81 stands on top of the front portion 27 of the module casing 21 of a lower one of the keyboard modules 2 in the stack. The bottom wall 26 of the module casing 21 of each keyboard module 2 is formed with a receiving groove 82 for receiving the support member 81 when the latter is at the folded position. In this embodiment, the support member 81 includes a plate body connected pivotally to the bottom wall 26 of the module casing 21.

Preferably, the bottom wall 26 of the module casing 21 of each keyboard module 2 is further formed with a pair of foot posts 83. Each support member 81 is also formed with a pair of foot posts 83. The front portion 27 of the module casing 21 of each keyboard module 2 is formed with a groove 80 for receiving a tip 810 of the support member 81 on another keyboard module 2. The rear portion 28 of the module casing 21 of each keyboard module 2 is further formed with a pair of post grooves 830. When the keyboard modules 2 are arranged to form the stack, the foot posts 83 on the bottom wall 26 of an upper one of the keyboard modules 2 extend into the post grooves 830 in the rear portion 28 of the module casing 21 of a lower one of the keyboard modules 2, and the tip 810 of the support member 81 on the upper one of the keyboard modules 2 extends into the groove 80 in the front portion 27 of the module casing 21 of the lower one of the keyboard modules 2. By selecting the dimensions of the foot posts 83 and the support member 81, a clearance 210 can be formed between the bottom wall 26 of the module casing 21 of the upper keyboard module 2 and the module casing 21 of the lower keyboard module 2 so as to prevent possible damage to the keyboard modules 2 due to scraping therebetween. Moreover, because the support member 81 is in the form of a plate, the finger keys 221 can be concealed as well when the keyboard modules 2 are arranged to form the stack.

Referring further to FIG. 6, aside from retaining removably the keyboard modules 2 in the stack, the tie rods 91 can also be used to secure the keyboard modules 2 when the elongate keyboard body is formed.

Referring again to FIG. 1, the keyboard modules 2 can be further provided with function keys 24 for functions like echo, beat, etc., and control keys 25 for volume, tempo, etc., on the module casings 21 thereof. Signals generated upon operation of the function keys 24 and the control keys 25 can be similarly provided to the signal port 4 via the signal lines 11 of the signal bus 10 and the connecting devices 3 in order to enable the encoder 5 to control the processor 6 to result in the desired sound effects.

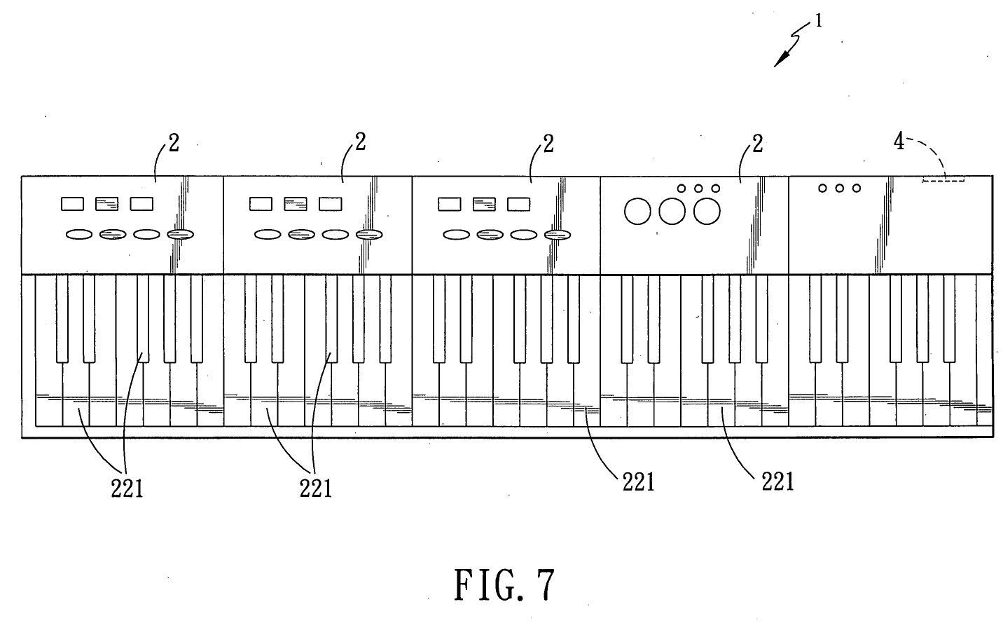

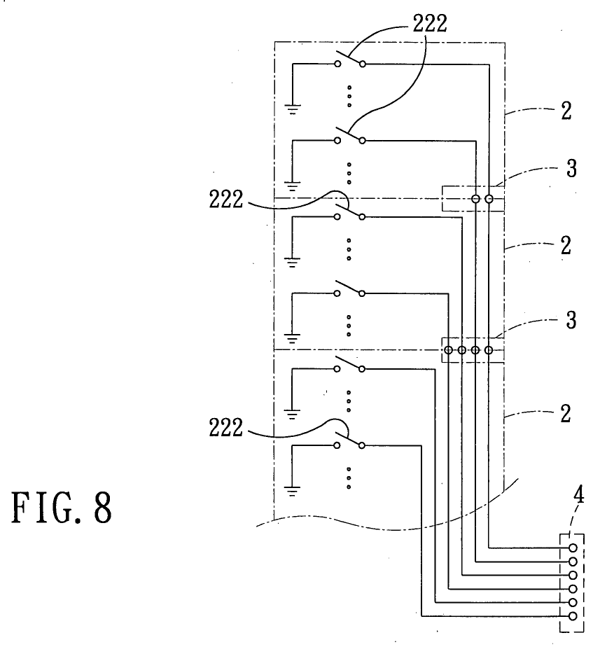

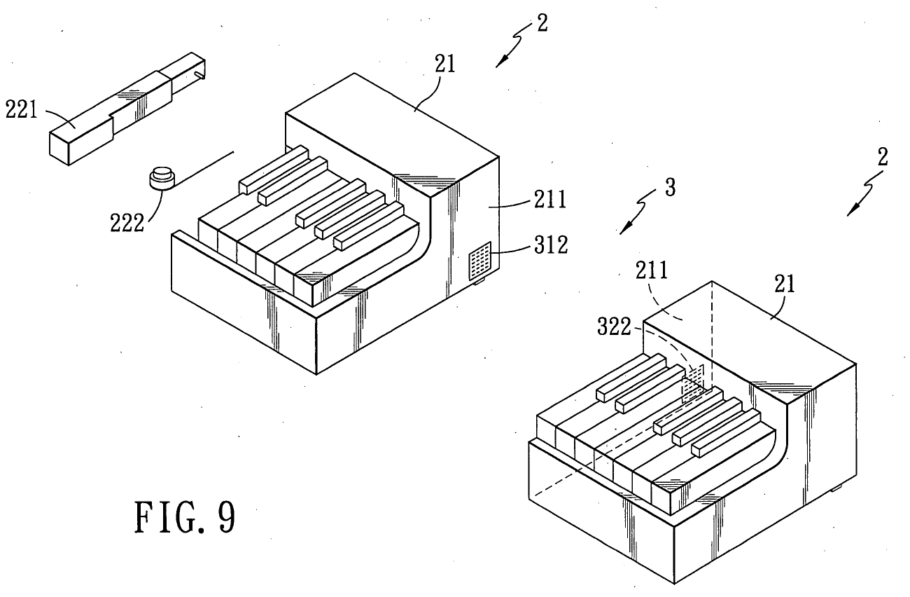

FIGS. 7 to 9 illustrate the second preferred embodiment of a modular electronic musical keyboard instrument 1 according to the present invention. Unlike the previous embodiment, none of the keyboard modules 2 is provided with the encoder, the processor, and the speaker. Hence, the instrument 1 of this embodiment must be used in conjunction with an external device (not shown) that is connected to the signal port 4 for sound reproduction purposes. This embodiment further differs from the previous embodiment in the configuration of the connecting devices 3. In this embodiment, the module casings 21 of each adjacent pair of the keyboard modules 2 of the elongate keyboard body have confronting lateral walls 211. Each of the connecting devices 3 includes a set of first electrical contacts 312 mounted on the lateral wall 211 of the module casing 21 of a first one of the keyboard modules 2 in the corresponding adjacent pair, and a set of second electrical contacts 322 mounted on the lateral wall 211 of the module casing 21 of a second one of the keyboard modules 2 in the corresponding adjacent pair for connecting electrically and respectively with the first electrical contacts 312 when the elongate keyboard body is formed. Like the previous embodiment, the keyboard modules 2 can be arranged in a stack to facilitate storage and handling.

In sum, the modular electronic musical keyboard instrument 1 of the present invention permits stacking of the keyboard modules 2 to facilitate storage and handling. Moreover, due to the modular configuration of the present invention, upgrading from a smaller number to a larger number of the keyboard modules 2 is permissible, thereby resulting in greater flexibility for the modular electronic musical keyboard instrument 1 of this invention.

While the present invention has been described in connection with what is considered the most practical and preferred embodiments, it is understood that this invention is not limited to the disclosed embodiments but is intended to cover various arrangements included within the spirit and scope of the broadest interpretation so as to encompass all such modifications and equivalent arrangements.

1. A modular electronic musical keyboard instrument comprising:
a plurality of keyboard modules, each of which includes a module casing, a set of signal switches mounted on said module casing, and a set of finger keys mounted operably on said module casing and associated operably and respectively with said signal switches for controlling activation and deactivation of said signal switches;
a signal bus including a plurality of signal lines, each of which is connected electrically to a corresponding one of said signal switches, said signal bus being divided into a plurality of bus sections, each of which is disposed in said module casing of a respective one of said keyboard modules;
a plurality of connecting devices, each of which connects electrically said bus sections of a corresponding adjacent pair of said keyboard modules when said module casings of said keyboard modules are disposed side by side to form an elongate keyboard body; and
a signal port connected electrically to said signal bus.

2. The modular electronic musical keyboard instrument as claimed in claim 1, further comprising an encoder coupled electrically to said signal port and responsive to activation of said signal switches that are connected to said encoder via said signal bus and said signal port so as to generate a corresponding command.

3. The modular electronic musical keyboard instrument as claimed in claim 2, further comprising a processor coupled electrically to said encoder and responsive to the command issued by said encoder so as to generate a corresponding audio signal output.

4. The modular electronic musical keyboard instrument as claimed in claim 3, wherein said processor includes a sound effect generator coupled electrically to said encoder, and an amplifier coupled electrically to said sound effect generator.

5. The modular electronic musical keyboard instrument as claimed in claim 4, further comprising a speaker coupled to said amplifier for reproducing the audio signal output of said processor.

6. The modular electronic musical keyboard instrument as claimed in claim 5, wherein said signal port, said encoder, said processor, and said speaker are disposed in said module casing of one of said keyboard modules.

7. The modular electronic musical keyboard instrument as claimed in claim 1, wherein said module casings of each said adjacent pair of said keyboard modules of said elongate keyboard body have confronting lateral walls,
said module casing of a first one of said keyboard modules in each said adjacent pair further having a top wall formed with a contact receiving recess that opens to said lateral wall thereof,
said module casing of a second one of said keyboard modules in each said adjacent pair being formed with a contact support plate that extends removably into said contact receiving recess of said module casing of said first one of said keyboard modules,
each of said connecting devices including a set of first electrical contacts mounted in said contact receiving recess, and a set of second electrical contacts mounted on said contact support plate for connecting electrically and respectively with said first electrical contacts when said contact support plate is extended into said contact receiving recess.

8. The modular electronic musical keyboard instrument as claimed in claim 7, wherein each of said connecting devices further includes a press member mounted movably on said top wall of said module casing of said first one of said keyboard modules in the corresponding adjacent pair of said keyboard modules adjacent to said contact receiving recess,
said press member being movable to a pressing position, where said press member presses said contact support plate downward to ensure electrical connection between said first and second electrical contacts.

9. The modular electronic musical keyboard instrument as claimed in claim 1, wherein said finger keys of each of said keyboard modules include seven monotone keys and five halftone keys.

10. The modular electronic musical keyboard instrument as claimed in claim 1, wherein said module casing of each of said keyboard modules has a front portion, a rear portion that is raised relative to said front portion, and a bottom wall, said finger keys being disposed on said front portion of said module casing,
said module casings of said keyboard modules being capable of being stacked one on top of the other such that said bottom wall of said module casing of an upper one of said keyboard modules is supported on top of said rear portion of said module casing of a lower one of said keyboard modules, thereby forming a stack,
said modular electronic musical keyboard instrument further comprising a set of tie rods, each of which has opposite ends connected removably to a corresponding pair of said keyboard modules in said stack.

11. The modular electronic keyboard instrument as claimed in claim 10, wherein said module casing of said upper one of said keyboard modules further has a support member connected foldably to said bottom wall thereof and foldable away from said bottom wall from a folded position to an unfolded position where said support member stands on top of said front portion of said module casing of said lower one of said keyboard modules in said stack.

12. The modular electronic musical keyboard instrument as claimed in claim 11, wherein said bottom wall of said module casing of said upper one of said keyboard modules is formed with a receiving groove for receiving said support member when said support member is at the folded position.

13. The modular electronic musical keyboard instrument as claimed in claim 11, wherein said support member includes a plate body connected pivotally to said bottom wall of said module casing of said upper one of said keyboard modules.

14. The modular electronic musical keyboard instrument as claimed in claim 10, wherein said module casing of each of said keyboard modules has front and rear walls, at least one of which is formed with a rod engaging hole,
said opposite ends of each of said tie rods extending removably into said rod engaging holes in said corresponding pair of said keyboard modules in said stack.

15. The modular electronic musical keyboard instrument as claimed in claim 1, further comprising a set of tie rods, each of which has opposite ends connected removably to a corresponding pair of said keyboard modules of said elongate keyboard body.

16. The modular electronic musical keyboard instrument as claimed in claim 15, wherein said module casing of each of said keyboard modules has front and rear walls, at least one of which is formed with a rod engaging hole,
said opposite ends of each of said tie rods extending removably into said rod engaging holes in said corresponding pair of said keyboard modules of said keyboard body.

17. The modular electronic musical keyboard instrument as claimed in claim 1, wherein said module casings of each said adjacent pair of said keyboard modules of said elongate keyboard body have confronting lateral walls,
each of said connecting devices including a set of first electrical contacts mounted on said lateral wall of said module casing of a first one of said keyboard modules in the corresponding adjacent pair, and a set of second electrical contacts mounted on said lateral wall of said module casing of a second one of said keyboard modules in the corresponding adjacent pair for connecting electrically and respectively with said first electrical contacts when said elongate keyboard body is formed.
